(19) United States
(12) Patent Application Publication
(10) Pub. No.: US 2002/0100979 A1
(43) Pub. Date: Aug. 1, 2002

(54) Semiconductor structure for measuring dielectric constant and clarifying polarization effect of interlevel dielectric layer

(76) Inventor: Mu-Chun Wang, Hsin-Chu (TW)

Correspondence Address: Powell, Goldstein, Frazer & Murphy, LLP, Suite 600, 1001 Pennsylvanic Avenue, Washington, DC, 20004, US

(21) Appl. No.: 09/774,454

(22) Filed: Jan. 31, 2001

(51) Int. Cl. H01L 23/48; H01L 23/52; H01L 29/40

(52) U.S. Cl. 257/758; 257/760; 257/762; 257/763; 257/774; 257/776; 257/784

(57) ABSTRACT

A semiconductor structure for measuring a dielectric constant and clarifying a polarization effect of an interlevel dielectric layer is disclosed. The semiconductor structure comprises a substrate having a conductive layer thereon, an interlevel dielectric layer formed over the substrate, and a plurality of via walls formed into the interlevel dielectric layer connecting, overlapping and aligning with the conductive layer. The conductive layer comprises two areas of equidistant conductive lines and two conductive lines. Each area comprises two pluralities of equidistant conductive lines and one interposed individually between the other. The pluralities of equidistant conductive lines of the two areas are perpendicular to each other and connected by the two conductive lines. The via walls comprises pluralities of equidistant via walls connecting and aligning with the pluralities of equidistant conductive lines of the two areas.

### BACKGROUND OF THE INVENTION

1. Field of the Invention

The present invention relates to a semiconductor structure for measuring a dielectric constant layer and clarifying a polarization effect of interlevel dielectric (ILD) layer in an integrated circuit, and more particularly to a semiconductor structure having metal via walls therein for measuring a dielectric constant and clarifying a polarization effect of interlevel dielectric layer in an integrated circuit.

2. Description of the Related Art

The native capacitance stemming from the parasitic capacitor comprising metal lead lines and interlevel dielectric (ILD) layers hampers the operating speed of deep-submicron devices. Therefore, in view of the demand of higher performance, modern integrated circuits require low k (Dielectric Constant) ILD materials to efficiently reduce the native capacitance. In addition, measuring the dielectric constant of the ILD layer precisely is a very crucial issue in modern deep-submicron integrated circuit processes.

Unfortunately, measuring the dielectric constant of the ILD layer accurately is somewhat troublesome. More particularly, in many types of the ILD materials, the dielectric constant is not isotropic, i.e., the dielectric constant is often lower through the thickness (z-axis) of the dielectric film than it is in-plane (xy-plane). Thus, while many reported values of low dielectric constant materials report only the through-thickness result, it is the in-plane dielectric constant that is also important for the application of an integrated circuit dielectric material. The xy-plane dielectric constant determines the line-to-line capacitance, which is the dominant component of RC time delay in integrated circuits.

Typically, measurement of dielectric constant in the z-axis is performed through the use of a metal-insulator-metal (MIM) parallel plate capacitor structure. As shown in FIG. 1A, an ILD layer 108 is clamped by metal lines 102, 104 in an integrated circuit. The dielectric constant is calculated by determining the capacitance of the MIM structure. For the dielectric constant to be calculated accurately, it is important that both the area of the MIM and the insulator thickness be known. Additionally, another common technique employed to measure the dielectric constant in the z-axis uses a liquid mercury probe as the upper metal surface. Use of the mercury probe is simple; however, its use is complicated by the fact that the actual mercury probe contact area is not well known. It can vary greatly since the mercury has an extremely high surface tension and does not reproducibly wet the same surface with the same contact area. At times, the dielectric constant of material is reported as a simple square of the material's index of refraction. This type of dielectric constant measurement permits calculations of dielectric constants both in the xy-plane and the z-axis of a thin film. However, such a dielectric constant measurement is determined at optical frequencies, which is significantly different from the dielectric constant of the material at typical frequencies used in electronic signal propagation. As is well known, measurement of the dielectric constant by the simple square of the index of refraction typically understates the dielectric constant by an amount equal to approximately 0.2.

Except the problems of deciding the dielectric constant of the dielectric material mentioned above, measuring the dielectric constant of the ILD layer in a high integration integrated circuit with multilevel interconnects is another tough issue. The dielectric constant of the ILD layer formed by various processes is usually measured by using via chain semiconductor structures. However, because the vias are metal plugs within the ILD layer, which means they are intermittent, not continuous within the ILD layer, the dielectric constant measurement of the ILD layer having metal vias therein is more or less inaccurate. FIG. 1B shows metal vias 106 within the ILD layer 108, and the metal lines 102, 104 that clamp the ILD layer 108. Moreover, the polarization phenomenon or anisotropic property of the ILD layer 108 render the issue more complicated. Therefore, it is very necessary to provide a new structure for precisely measuring the dielectric constant and clarifying the polarization phenomenon of the ILD layer in a deep-submicron integrated circuit. It is towards those goals that the present invention is specifically directed.

### SUMMARY OF THE INVENTION

It is therefore an object of the invention to provide a semiconductor structure for precisely measuring a dielectric constant of an ILD layer in a high integration integrated circuit.

It is another object of this invention to provide a semiconductor structure for individually measuring dielectric constants in the xy-plane and the z-axis of an ILD layer in a high integration integrated circuit.

It is a further object of this invention to provide a semiconductor structure to find the polarization effect of an ILD layer.

To achieve these objects, and in accordance with the purpose of the invention, the invention use a semiconductor structure having a plurality of equidistant parallel via walls for measuring a dielectric constant and clarifying a polarization effect of an interlevel dielectric layer is disclosed. The semiconductor structure comprises a substrate having a conductive layer thereon, an interlevel dielectric layer formed over the substrate, and a plurality of via walls formed into the interlevel dielectric layer connecting and aligning with the conductive layer. The conductive layer comprises two areas of equidistant parallel conductive lines and two conductive lines. Each area comprises two pluralities of equidistant parallel conductive lines and one interposed individually between the other. The pluralities of equidistant parallel conductive lines of the two areas are perpendicular to each other and connected by the two conductive lines. The via walls comprise pluralities of equidistant parallel via walls connecting and aligning with the pluralities of equidistant parallel conductive lines of the two areas.

It is to be understood that both the foregoing general description and the following detailed description are exemplary and explanatory only and are not restrictive of the invention, as claimed.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1A shows two metal lines separated by an ILD layer in an integrated circuit;

FIG. 1B shows metal vias within the ILD layer shown in FIG. 1A, and connecting the metal lines;

FIG. 2A shows a first portion of a multilayer structure in an integrated circuit;

FIG. 2B shows a second portion of the multilayer structure in the integrated circuit;

FIG. 2C shows a third portion of the multilayer structure in the integrated circuit; and

FIG. 2D and 2E are top views of the integrated circuit.

### DESCRIPTION OF THE PREFERRED EMBODIMENT

It is to be understood and appreciated that the process steps and structures described below do not cover a complete process flow. The present invention can be practiced in conjunction with various integrated circuit fabrication techniques that are used in the art, and only so much of the commonly practiced process steps are included herein as are necessary to provide an understanding of the present invention.

The present invention will be described in detail with reference to the accompanying drawings. It should be noted that the drawings are in greatly simplified form and they are not drawn to scale. Moreover, dimensions have been exaggerated in order to provide a clear illustration and understanding of the present invention.

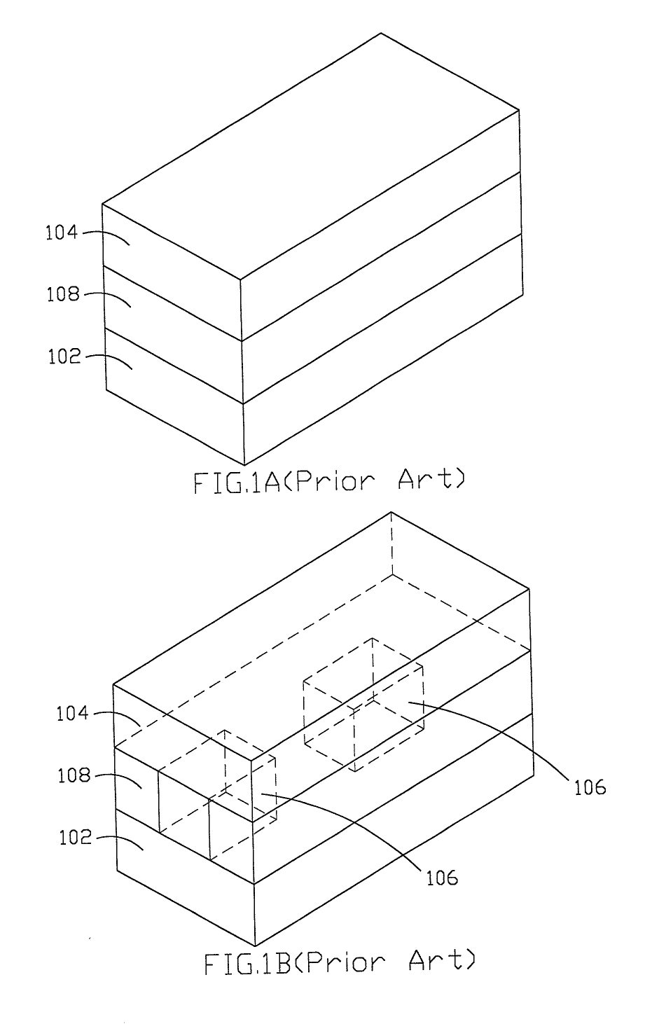

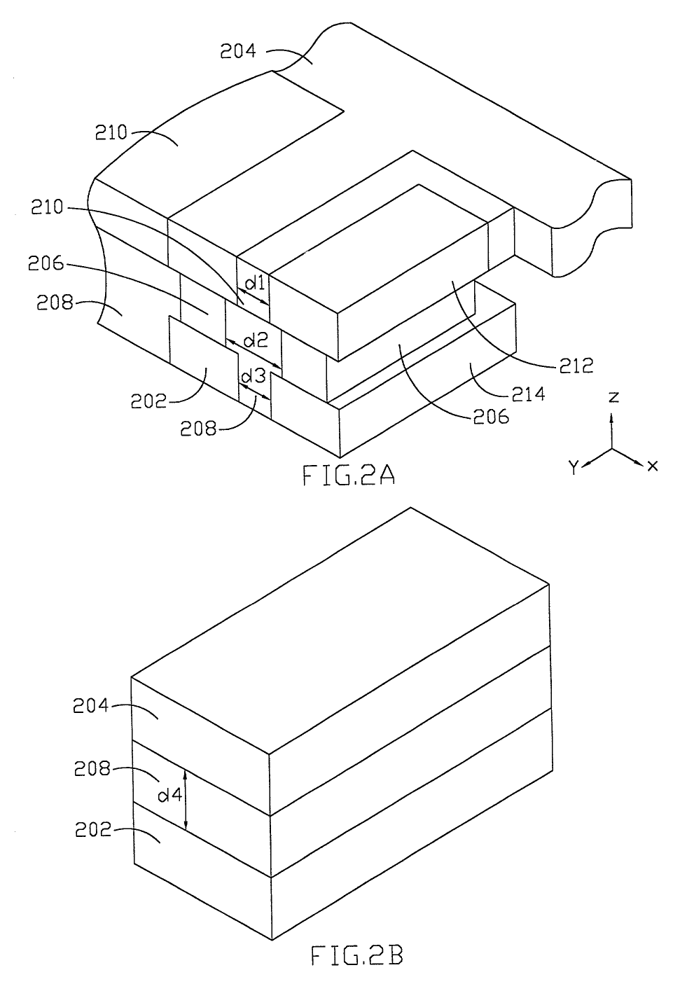

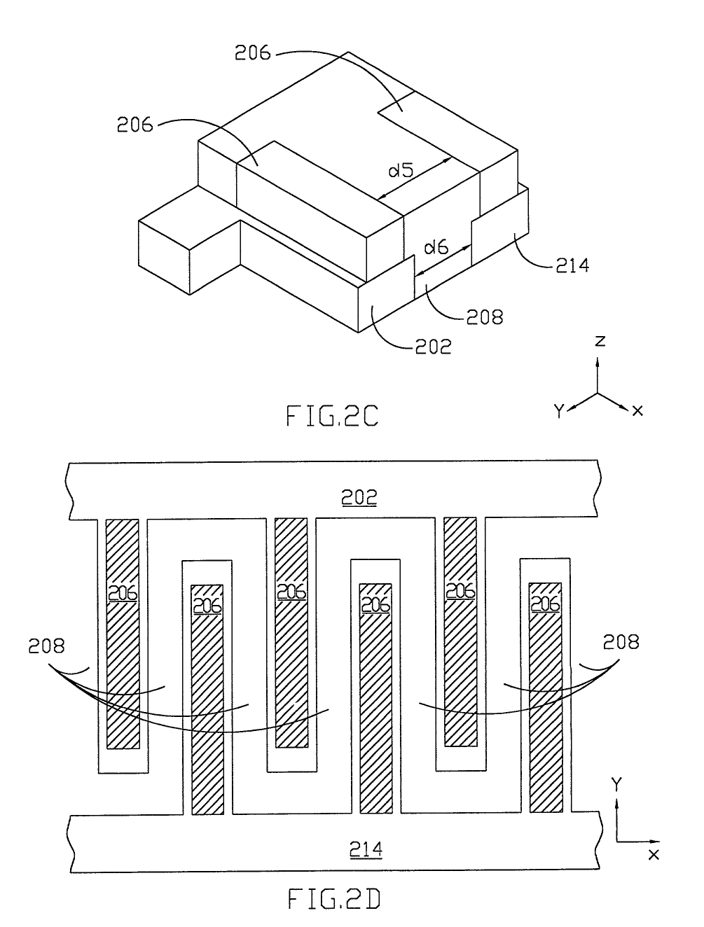

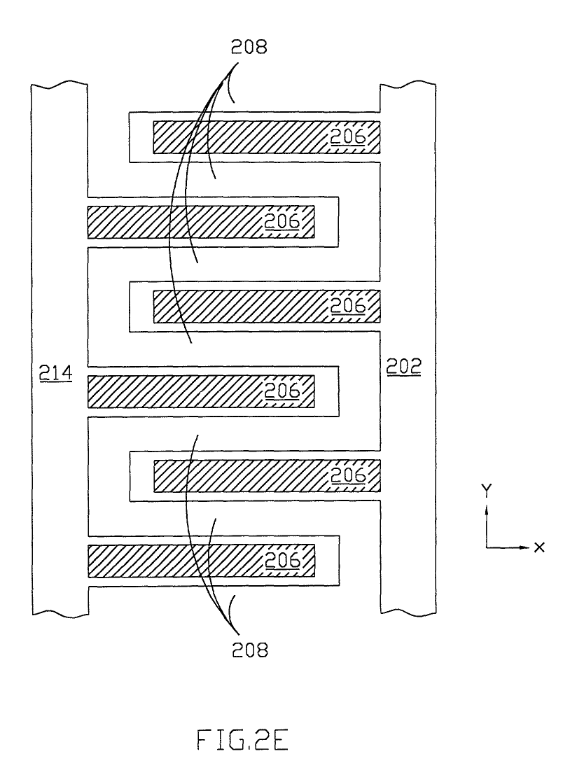

Referring to FIG. 2A, a first portion of multilevel interconnects of a high integration integrated circuit is shown. The illustrated structure shows via walls 206 connecting top metal lines 204 and 212, bottom metal lines 202 and 214, and ILD layers 208 and 210. It is noted that a substrate having various devices therein under the illustrated structure are not shown. The substrate can be a semiconductor substrate and is preferably a silicon substrate. Instead of the use of via plugs in the art as shown in FIG. 1B, the invention utilizes via walls to connect the metal lines of different levels. The via wall 206, like the vias 106, can be tungsten (W) and aluminum (Al), and it is preferably tungsten. The metal lines 202, 204, 212 and 214 can be a conventional conductive material used as lead lines in the art, for example, aluminum and copper.

The ILD layers 208, 210 can be conventional dielectric materials used as ILD layers in the art, for example, silicon dioxide layers deposited by using plasma enhanced chemical vapor deposition (PECVD) processes and spin-on-glass (SOG) layers. The via wall 206 can be formed by using the conventional method that used to form via plugs. First of all, a substrate having the ILD layer 208 thereon is provided. Then a trench pattern parallel to the metal lines 202 and 214 is transferred into the ILD layer 208 to expose the metal lines 202 and 214 by using conventional photolithography and etching processes. The etching process is preferably a dry etching process, for example, a reactive ion etching (RIE) process that uses a carbon tetrafluoride (CF₄) plasma. Then a conductive layer is formed over the substrate by using a chemical vapor deposition (CVD) process. For a W via wall, a blanket tungsten layer is deposited by using a low pressure chemical vapor deposition (LPCVD) process. A titanium nitride (TiN) or a titanium tungsten (TiW ) layer is often previously formed to serve as a glue layer. Next the conductive layer over the ILD layer 208 is removed by using a dry etching process or a chemical mechanical polishing (CMP) process, for a W layer, the process is also called a W etch back process. Finally, the ILD layer 210 and the metal lines 204 and 212 are sequentially formed by using conventional methods. The illustrated structure set forth is used to measure the x-axis dielectric constant of the ILD layer 208. For a measured capacitance C, C=kε₀A/d, wherein k is the dielectric constant of the dielectric material, A is the area of the electrode of the capacitance C, ε ₀ is permittivity of free space, and d is the thickness of the dielectric material. In FIG. 2A, the x-direction dielectric constant kₓ of the ILD layers 208 can be obtained by measuring C_{X} and solving the equation, Cₓ=kₓ ε ₀A₂/d₂+kₓ ε ₀A₃/d₃, wherein Cₓ is the equivalent capacitance of the capacitor formed by connecting the capacitor of the via walls 206 and the capacitor of the metal lines 202 and 214 in parallel, A₂ and A₃ are the sidewall areas of the via walls 206 and the metal lines 202 and 214 separately, d₂ and d₃ are the distances of the neighboring via walls 206 and the neighboring metal lines 202 and 214 individually. The x-direction dielectric constant of the ILD layers 210 can be measured in a similar manner.

Referring to FIG. 2B, a second portion of the multilevel interconnects of the high integration integrated circuit is shown. This structure, which is similar to the one shown in FIG. 1A, is used to measure the z-axis dielectric constant of the ILD layer 208. The z-direction dielectric constant k_{z} of the ILD layer 208 can be found by measuring C_{z} and solving the equation, C_{z}=k_{z}ε ₀A₄/d₄, wherein A₄ is the area of the electrode 202 or 204 of the capacitor shown in FIG. 2B, and d₄ is the distance between the electrodes 202 and 204.

Referring to FIG. 2C, a third portion of the multilevel interconnects of the high integration integrated circuit is shown. Similar to the structure shown in FIG. 2A, the illustrated structure, which has a perpendicular relation therewith, is used to measure the y-axis dielectric constant of the ILD layer 208. In addition, the y-direction dielectric constant k_{y} of the ILD layer 208 can be calculated by measuring C_{y} and solving the equation, C_{y}=k_{y} ε ₀A₅/d₅+k_{y} ε ₀A₆/d₆, wherein A₅ and A₆ are the sidewall areas of the via walls 206 and the metal lines 202 and 214 separately, d₅ and d₆ are the distances of the neighboring via walls 206 and the neighboring metal lines 202 and 214 individually. The ILD layer 210, the metal lines 204 and 212 are omitted in this figure.

Referring now to FIG. 2D and FIG. 2E, whole top views of the structures shown in FIG. 2A and FIG. 2C are separately shown. It is noted that metal lines 204, 212 on the via walls 206 and the ILD layer 210 are omitted for better understanding. Furthermore, the via walls 206, the metal lines 202 and 214 are equidistant and parallel. The illustrated structures can be treated as a plurality of equal capacitors connected in parallel. Moreover, the two illustrated structures shown in FIG. 2D and 2E respectively can be connected by the metal lines 202 and 214 and formed on the same substrate to find the x-direction and the y-direction dielectric constants of the ILD layer 208 at the same time. As shown in FIG. 2D and 2E, the x-direction and the y-direction dielectric constants of the ILD layer 208 having the equidistant parallel via walls 206 therein can be measured respectively by applying a voltage to the metal line 202 and connecting the metal line 214 to a ground potential and vice versa. The formation of this illustrated structures used to measure the dielectric constant and detect the polarization effect of the ILD layer are from the circuit design phase to the integrated circuit processing.

The invention uses via walls to replace the via plugs used in the art to simplify the measurement of the dielectric constant and clarify the polarization effect of the ILD layer amid modern semiconductor device technologies. By using the semiconductor structure mentioned above, not only the dielectric constant of the ILD layer can be precisely calculated, but also the polarization effect of the ILD layer can be found. Thus one can efficiently analyze the ILD layer deposited in various conditions by this way.

Other embodiments of the invention will appear to those skilled in the art from consideration of the specification and practice of the invention disclosed herein. It is intended that the specification and examples to be considered as exemplary only, with a true scope and spirit of the invention being indicated by the following claims.

What is claim is:

1. A semiconductor structure for measuring a dielectric constant and clarifying a polarization effect of an interlevel dielectric layer, said semiconductor structure comprising:
(a) a substrate;
(b) a conductive layer on said substrate, said conductive layer comprising:
(b1) a plurality of equidistant first conductive lines;
(b2) a first conductor perpendicularly connecting one end of each one of said plurality of first conductive lines;
(b3) a plurality of equidistant second conductive lines interposed individually between and to said plurality of first conductive lines; and
(b4) a second conductor perpendicularly connecting one end of each one of said plurality of second conductive lines;
(c) a plurality of equidistant via walls on said plurality of first conductive lines and said plurality of second conductive lines, and connecting and aligning therewith; and
(d) an interlevel dielectric layer on said substrate and between said plurality of first conductive lines, said plurality of second conductive lines and said plurality of via walls.

2. The semiconductor structure according to claim 1, wherein said conductive layer is a copper layer.

3. The semiconductor structure according to claim 1, wherein said conductive layer is an aluminum layer.

4. The semiconductor structure according to claim 1, wherein said interlevel dielectric layer is a spin-on glass layer.

5. The semiconductor structure according to claim 1, wherein said interlevel dielectric layer is a silicon dioxide layer.

6. The semiconductor structure according to claim 1, wherein said via walls are tungsten via walls.

7. The semiconductor structure according to claim 1, wherein said via walls are aluminum via walls.

8. A semiconductor structure for measuring a dielectric constant and clarifying a polarization effect of an interlevel dielectric layer, said semiconductor structure comprising:
(a) a substrate;
(b) a first conductive layer on said substrate, said first conductive layer comprising:
(b1) a plurality of equidistant first conductive lines;
(b2) a first conductor perpendicularly connecting one end of each one of said plurality of first conductive lines;
(b3) a plurality of equidistant second conductive lines interposed individually between and to said plurality of first conductive lines; and
(b4) a second conductor perpendicularly connecting one end of each one of said plurality of second conductive lines;
(c) a plurality of equidistant first via walls on said plurality of first conductive lines, and connecting and aligning therewith;
(d) a plurality of equidistant second via walls on said plurality of second conductive lines, and connecting and aligning therewith;
(e) an interlevel dielectric layer on said substrate and between said plurality of first conductive lines, said plurality of second conductive lines, said plurality of first via walls and said plurality of second via walls;
(f) a second conductive layer on said interlevel dielectric layer, said second conductive layer comprising:
(f1) a plurality of equidistant third conductive lines on said plurality of first via walls, and connecting and aligning therewith;
(f2) a third conductor perpendicularly connecting one end of each one of said plurality of third conductive lines;
(f3) a plurality of equidistant fourth conductive lines on said plurality of second via walls, and connecting and aligning therewith; and
(f4) a fourth conductor perpendicularly connecting one end of each one of said plurality of fourth conductive lines;

9. The semiconductor structure according to claim 8, wherein said first conductive layer is a copper layer.

10. The semiconductor structure according to claim 8, wherein said first conductive layer is an aluminum layer.

11. The semiconductor structure according to claim 8, wherein said interlevel dielectric layer is a spin-on glass layer.

12. The semiconductor structure according to claim 8, wherein said interlevel dielectric layer is a silicon dioxide layer.

13. The semiconductor structure according to claim 8, wherein said first and second via walls are tungsten via walls.

14. The semiconductor structure according to claim 8, wherein said first and second via walls are aluminum via walls.

15. The semiconductor structure according to claim 8, wherein said second conductive layer is a copper layer.

16. The semiconductor structure according to claim 8, wherein said second conductive layer is an aluminum layer.

17. A semiconductor structure for measuring a dielectric constant and clarifying a polarization effect of an interlevel dielectric layer, said semiconductor structure comprising:
(a) a substrate;
(b) a conductive layer on said substrate, said conductive layer comprising:
(b1) a plurality of equidistant first conductive lines;
(b2) a first conductor perpendicularly connecting one end of each one of said plurality of first conductive lines;
(b3) a plurality of equidistant second conductive lines interposed individually between and to said plurality of first conductive lines; and
(b4) a second conductor perpendicularly connecting one end of each one of said plurality of second conductive lines;
(b5) a plurality of equidistant third conductive lines perpendicular to said plurality of first conductive lines;
(b6) a third conductor perpendicularly connecting one end of each one of said plurality of third conductive lines and said first conductor;
(b7) a plurality of equidistant fourth conductive lines interposed individually between and to said plurality of third conductive lines; and
(b8) a fourth conductor perpendicularly connecting one end of each one of said plurality of fourth conductive lines and said second conductor;
(c) a plurality of equidistant first via walls on said plurality of first conductive lines and said plurality of second conductive lines, and connecting and aligning therewith;
(d) a plurality of equidistant second via walls on said plurality of third conductive lines and said plurality of fourth conductive lines, and connecting and aligning therewith; and
(e) an interlevel dielectric layer on said substrate and between said plurality of first conductive lines, said plurality of second conductive lines, said plurality of third conductive lines, said plurality of fourth conductive lines, said first plurality of via walls and said second plurality of via walls.

18. The semiconductor structure according to claim 17, wherein said conductive layer is a copper layer.

19. The semiconductor structure according to claim 17, wherein said conductive layer is an aluminum layer.

20. The semiconductor structure according to claim 17, wherein said interlevel dielectric layer is a spin-on glass layer.

21. The semiconductor structure according to claim 17, wherein said interlevel dielectric layer is a silicon dioxide layer.

22. The semiconductor structure according to claim 17, wherein said first and second via walls are tungsten via walls.

23. The semiconductor structure according to claim 17, wherein said first and second via walls are aluminum via walls.
